(19) United States
(12) Patent Application Publication
(10) Pub. No.: US 2020/0251678 A1
(43) Pub. Date: Aug. 6, 2020

(54) ORGANIC ELECTROLUMINESCENT DISPLAY PANEL, MANUFACTURING METHOD THEREOF AND DISPLAY DEVICE

(71) Applicant: BOE TECHNOLOGY GROUP CO., LTD., Beijing (CN)

(72) Inventors: Zhen SONG, Beijing (CN); Guoying WANG, Beijing (CN)

(21) Appl. No.: 16/652,037

(22) PCT Filed: Jun. 18, 2019
(86) PCT No.: PCT/CN2019/091676

§ 371 Date: Mar. 28, 2020

(30) Foreign Application Priority Data
Jun. 20, 2018 (CN) 201810638529.4

(51) Int. Cl. H01L 51/52; H01L 27/32; H01L 51/56; H01L 51/00

(52) U.S. Cl. CPC H01L 51/5218; H01L 51/5271; H01L 27/3246; H01L 51/5246; H01L 2251/5315; H01L 51/56; H01L 51/0023; H01L 2251/301; H01L 2251/303; H01L 51/5212

(57) ABSTRACT

The present disclosure provides an organic electroluminescent display panel, a manufacturing method thereof, and a display device. The organic electroluminescent display panel includes a base substrate including a plurality of pixel regions and a non-pixel region between adjacent pixel regions. Each pixel region includes a reflective anode, the non-pixel region includes a support portion and a reflective portion on top of the support portion. For each reflective anode and a reflective portion directly adjacent to the reflective anode, a gap is between the reflective anode and the reflective portion, and an orthographic projection of the reflective anode on the base substrate and an orthographic projection of the reflective portion on the base substrate have a common edge.

### RELATED APPLICATIONS

The present application claims the benefit of Chinese Patent Application No. 201810638529.4, filed on Jun. 20, 2018, the entire disclosures of which are incorporated herein by reference.

### TECHNICAL FIELD

The present disclosure relates to the field of display technology, and in particular, to an organic electroluminescent display panel, a manufacturing method thereof, and a display device.

### BACKGROUND

Among flat panel display panels, the organic light emitting diode (OLED) display panels have attracted widespread attention due to their advantages such as self-luminous, fast response, wide viewing angle, high brightness, bright colors, thin and light. In the production of large-size OLED screens, it is difficult to achieve high resolution for the bottom emitting OLED device since it is affected by the aperture ratio. Therefore, more and more manufacturers are developing top emitting OLED devices to achieve high resolution.

In top emitting OLED devices, the reflective anode is usually a three-layer stack structure, such as ITO/Ag/ITO. In the related art, each laminated material of the reflective anode structure is produced by continuous deposition and continuous etching, and there is a gap of 5-7 um between the reflective anodes corresponding to adjacent sub-pixels. Therefore, after the display panel is lit, it is impossible to completely shield the TFTs (thin film transistors) on the back panel, which reduces the reliability of the back panel.

### SUMMARY

An embodiment of the present disclosure provides an organic electroluminescent display panel. The organic electroluminescent display panel includes: a base substrate including a plurality of pixel regions and a non-pixel region between adjacent pixel regions. Each pixel region includes a reflective anode; the non-pixel region includes a support portion and a reflective portion on top of the support portion. For each reflective anode and a reflective portion directly adjacent to the reflective anode, a gap is between the reflective anode and the reflective portion, and an orthographic projection of the reflective anode on the base substrate and an orthographic projection of the reflective portion on the base substrate have a common edge.

In some embodiments, an area of an orthographic projection of a surface of the support portion facing the reflective portion on the base substrate is larger than an area of an orthographic projection of a surface of the support portion facing away from the reflective portion on the base substrate.

In some embodiments, the support portion includes an upper section and a lower section; the upper section is between the reflective portion and the lower section, and an area of an orthographic projection of the upper section on the base substrate is larger than an area of an orthographic projection of the lower section on the base substrate.

In some embodiments, a material of the lower section is SiOx, and a material of the upper section is SiNx.

In some embodiments, a material of the reflective portion and a material of the reflective anode are the same.

In some embodiments, the organic electroluminescent display panel further includes a cathode covering the plurality of pixel regions and the non-pixel region. The cathode and the reflective portion are in direct contact.

In some embodiments, the non-pixel region further includes a pixel defining layer on the reflective portion. A portion of the pixel defining layer corresponding to the reflective portion has an opening. The cathode directly contacts the reflective portion in the opening.

In some embodiments, an area of an orthographic projection of the opening on the base substrate is smaller than an area of the orthographic projection of the reflective portion on the base substrate.

In some embodiments, the organic electroluminescent display panel further includes: a package cover plate disposed opposite to the base substrate, and a spacer layer on a side of the package cover plate facing the base substrate. The spacer layer corresponds to the opening.

In some embodiments, the organic electroluminescent display panel further includes an auxiliary electrode and a conductive layer. The auxiliary electrode is between the spacer layer and the package cover plate. An area of an orthographic projection of the auxiliary electrode on the base substrate is larger than an area of an orthographic projection of the spacer layer on the substrate. The conductive layer is electrically connected to the auxiliary electrode and covers the spacer layer and the package cover plate.

An embodiment of the present disclosure also provides a display device. The display device includes the organic electroluminescent display panel according to the above embodiments.

An embodiment of the present disclosure also provides a method for manufacturing the organic electroluminescent display panel as described in the above embodiments. The method includes: providing a base substrate including a plurality of pixel regions and a non-pixel region between adjacent pixel regions; forming a support portion in the non-pixel region; and forming a reflective anode in each pixel region and forming a reflective portion on top of the support portion. For each reflective anode and a reflective portion directly adjacent to the reflective anode, a gap is between the reflective anode and the reflective portion, and an orthographic projection of the reflective anode on the base substrate and an orthographic projection of the reflective portion on the base substrate have a common edge.

In some embodiments, an area of an orthographic projection of a surface of the support portion facing the reflective portion on the base substrate is larger than an area of an orthographic projection of a surface of the support portion facing away from the reflective portion on the base substrate.

In some embodiments, the support portion includes an upper section and a lower section; the upper section is between the reflective portion and the lower section. The step of forming the support portion in the non-pixel region includes: forming a stacked first dielectric layer and a second dielectric layer in the non-pixel region, the second dielectric layer being between the first dielectric layer and the base substrate; forming the upper section by performing a dry etching process on the first dielectric layer; and forming the lower section by performing a wet etching process on the second dielectric layer using the upper section as a mask pattern. An area of an orthographic projection of the upper section on the base substrate is larger than an area of an orthographic projection of the lower section on the base substrate.

In some embodiments, a material of the second dielectric layer is SiOx, and a material of the first dielectric layer is SiNx.

In some embodiments, the step of forming the reflective anode in each pixel region and forming the reflective portion on top of the support portion includes: forming the reflective anode in each pixel region and forming the reflective portion on top of the support portion by using a same patterning process.

### BRIEF DESCRIPTION OF THE DRAWINGS

In order to more clearly illustrate the technical solutions in embodiments of the disclosure or in the prior art, the appended drawings needed to be used in the description of the embodiments or the prior art will be introduced briefly in the following. Obviously, the drawings in the following description are only some embodiments of the disclosure, and for those of ordinary skills in the art, other drawings may be obtained according to these drawings under the premise of not paying out creative work.

FIG. 1 is a schematic structural diagram of an organic electroluminescent display panel according to an embodiment of the present disclosure;

FIG. 2 is a schematic structural diagram of an organic electroluminescent display panel according to another embodiment of the present disclosure;

FIG. 3 is a top view of a reflective anode and a reflective portion of an organic electroluminescent display panel according to an embodiment of the present disclosure;

FIG. 4 is a flowchart of a method for manufacturing an organic electroluminescent display panel according to an embodiment of the present disclosure;

FIG. 5 is a flowchart of a method for manufacturing an organic electroluminescent display panel according to another embodiment of the present disclosure; and

FIG. 6a to FIG. 6e are schematic structural diagrams corresponding to steps of a method for manufacturing an organic electroluminescent display panel according to an embodiment of the present disclosure.

### DETAILED DESCRIPTION OF THE DISCLOSURE

In the following, the technical solutions in embodiments of the disclosure will be described clearly and completely in connection with the drawings in the embodiments of the disclosure. Obviously, the described embodiments are only part of the embodiments of the disclosure, and not all of the embodiments. Based on the embodiments in the disclosure, all other embodiments obtained by those of ordinary skills in the art under the premise of not paying out creative work pertain to the protection scope of the disclosure.

The thickness, size and shape of each film layer in the drawings do not reflect the true scale of the display panel, but to schematically illustrate the content of the disclosure.

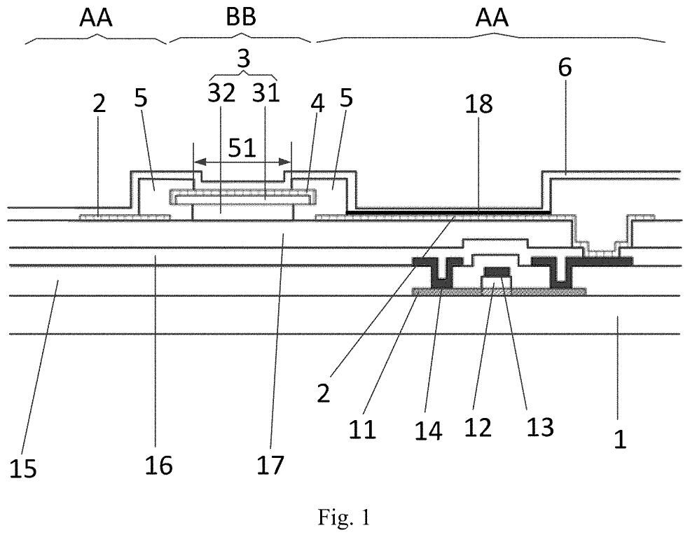

An embodiment of the present disclosure provides an organic electroluminescent display panel. As shown in FIG. 1 to FIG. 3, the organic electroluminescent display panel includes: a base substrate 1 including a plurality of pixel regions AA and a non-pixel region BB between adjacent pixel regions AA. Each pixel region AA includes a reflective anode 2; the non-pixel region BB includes a support portion 3 and a reflective portion 4 on top of the support portion 3. For each reflective anode 2 and a reflective portion 4 directly adjacent to the reflective anode 2, a gap is located between the reflective anode 2 and the reflective portion 4, and an orthographic projection of the reflective anode 2 on the base substrate 1 and an orthographic projection of the reflective portion 4 on the base substrate 1 have a common edge.

According to the organic electroluminescent display panel provided by the embodiment of the present disclosure, before the reflective anode is deposited, a support portion is provided in the non-pixel region. Therefore, when the material of the reflective anode is deposited, a gap is automatically formed between the reflective anode and a reflective portion directly adjacent to the reflective anode. The reflective anode is formed in the pixel region, and the reflective portion is formed in the non-pixel region. In this way, the independent reflective anodes are formed; moreover, the reflective anodes and the reflective portions completely cover the multiple pixel regions and the non-pixel region, which improves the light shielding effect on the devices (e.g., the thin film transistors) of the organic electroluminescent display panel and improves the reliability of the organic electroluminescent display panel.

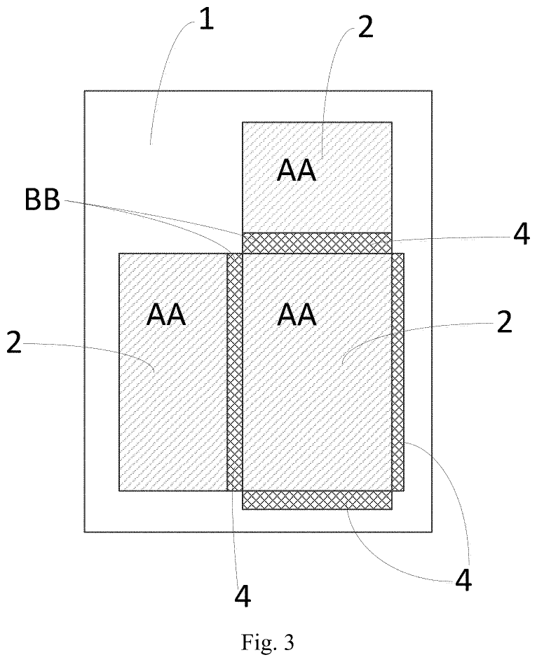

As shown in FIG. 3, the reflective portions 4 are formed between adjacent pixel regions AA, and the reflective anodes 2 are formed in the pixel regions AA. It can be seen that, for each reflective anode 2 and the reflective portion 4 directly adjacent to the reflective anode 2, a gap is formed between the reflective anode 2 and the reflective portion 4, and the orthographic projection of the reflective anode 2 on the base substrate 1 and the orthographic projection of the reflective portion 4 on the base substrate 1 have a common edge. Therefore, the reflective anodes and the reflective portions completely cover the multiple pixel regions and the non-pixel region, which improves the light shielding effect on the devices (e.g., the thin film transistors) of the organic electroluminescent display panel and improves the reliability of the organic electroluminescent display panel.

In some embodiments, an area of an orthographic projection of a surface of the support portion facing the reflective portion on the base substrate is larger than an area of an orthographic projection of a surface of the support portion facing away from the reflective portion on the base substrate.

In order to automatically separate the reflective anodes of adjacent pixel regions when the reflective anodes are deposited, in the above organic electroluminescent display panel provided by the embodiment of the present disclosure, as shown in FIG. 1, the area of the orthographic projection of the surface of the support portion 3 facing the reflective portion 4 on the base substrate 1 is larger than the area of the orthographic projection of the surface of the support portion 3 facing away from the reflective portion 4 on the base substrate 1. Since the support portion 3 has a certain thickness, when the material of the reflective anode is deposited, a gap is automatically formed between the reflective anode and the reflective portion directly adjacent to the reflective anode. The reflective anode is formed in the pixel region, and the reflective portion is formed in the non-pixel region. In this way, the independent reflective anodes are formed; moreover, the reflective anodes and the reflective portions completely cover the multiple pixel regions and the non-pixel region, which improves the light shielding effect on the devices (e.g., the thin film transistors) of the organic electroluminescent display panel and improves the reliability of the organic electroluminescent display panel.

In some embodiments, the support portion includes an upper section and a lower section; the upper section is located between the reflective portion and the lower section, and an area of an orthographic projection of the upper section on the base substrate is larger than an area of an orthographic projection of the lower section on the base substrate.

In order to automatically separate the reflective anodes of adjacent pixel regions more easily when the reflective anodes are deposited, in the above organic electroluminescent display panel provided by the embodiment of the present disclosure, as shown in FIG. 1, the support portion 3 includes an upper section 31 and a lower section 32; the upper section 31 is located between the reflective portion 4 and the lower section 32, and an area of the orthographic projection of the upper section 31 on the base substrate 1 is larger than an area of the orthographic projection of the lower section 32 on the base substrate 1.

In the above-mentioned organic electroluminescent display panel provided by the embodiment of the present disclosure, the support portion 3 includes the upper section 31 and the lower section 32. Those skilled in the art can understand that the support portion may also have other shapes, as long as the area of the orthographic projection of the surface of the support portion facing the reflective portion on the base substrate is larger than the area of the orthographic projection of the surface of the support portion facing away from the reflective portion on the base substrate.

In some embodiments, a material of the lower section is SiOx, and a material of the upper section is SiNx.

In the above-mentioned organic electroluminescent display panel provided by the embodiment of the present disclosure, as shown in FIG. 1, the material of the lower section 32 is SiOx, and the material of the upper section 31 is SiNx. The SiNx material is only longitudinally etched during dry etching, so the dry etching can be used to form the upper section 31 near the reflective portion 4. The SiOx material can be etched laterally during wet etching, so the wet etching can be used to form the lower section 32. Therefore, when the material of the reflective anode is deposited, a gap is automatically formed between the reflective anode and the reflective portion directly adjacent to the reflective anode. The reflective anode is formed in the pixel region, and the reflective portion is formed in the non-pixel region. In this way, the independent reflective anodes are formed; moreover, the reflective anodes and the reflective portions completely cover the multiple pixel regions and the non-pixel region, which improves the light shielding effect on the devices (e.g., the thin film transistors) of the organic electroluminescent display panel and improves the reliability of the organic electroluminescent display panel.

In some embodiments, a material of the reflective portion and a material of the reflective anode are the same. According to some embodiments of the present disclosure, the reflective portion and the reflective anode may be formed simultaneously using the same patterning process, thereby further simplifying the manufacturing process.

In some embodiments, the organic electroluminescent display panel further includes a cathode covering the plurality of pixel regions and the non-pixel region. The cathode and the reflective portion are in direct contact.

In some embodiments, the non-pixel region further includes a pixel defining layer on the reflective portion. A portion of the pixel defining layer corresponding to the reflective portion has an opening. The cathode directly contacts the reflective portion in the opening.

In order to avoid the phenomenon of light mixing between the pixel regions of the organic electroluminescent display panel, in the above-mentioned organic electroluminescent display panel provided by the embodiment of the present disclosure, as shown in FIG. 1, the non-pixel region further includes a pixel defining layer 5 located on the reflective portion 4; the pixel defining layer 5 defines the pixel region and the non-pixel region. The organic electroluminescent display panel may further include a cathode 6 located on the pixel defining layer 5 and covering the reflective anode 2 and the reflective portion 4. Those skilled in the art can understand that the organic electroluminescent display panel further includes a light emitting layer 18 located between the reflective anode 2 and the cathode 6. A portion of the pixel defining layer 5 corresponding to the reflective portion 4 has an opening 51. The cathode 6 directly contacts the reflective portion 4 through the opening 51. The material of the reflective portion is the same as that of the reflective anode, so the material of the reflective portion may be a conductive material such as a metal. The reflective portion 4 is in direct contact with the cathode 6, which increases the effective thickness of the cathode 6, so that the resistance of the cathode 6 can be reduced. Therefore, the problem of a large voltage drop due to a large resistance of the cathode 6 can be avoided, and the problem of damaging the display panel due to the large voltage drop can be avoided.

In some embodiments, an area of an orthographic projection of the opening 51 on the base substrate 1 is smaller than an area of an orthographic projection of the reflective portion 4 on the base substrate 1. In this way, the opening 51 of the pixel defining layer 5 can expose a part of the reflective portion 4. When the cell aligning process is performed on the display panel in a subsequent manufacturing process, the distance between the reflective portion 4 and the cathode 6 can be made small due to the pressure applied by the spacer layer on the package cover plate.

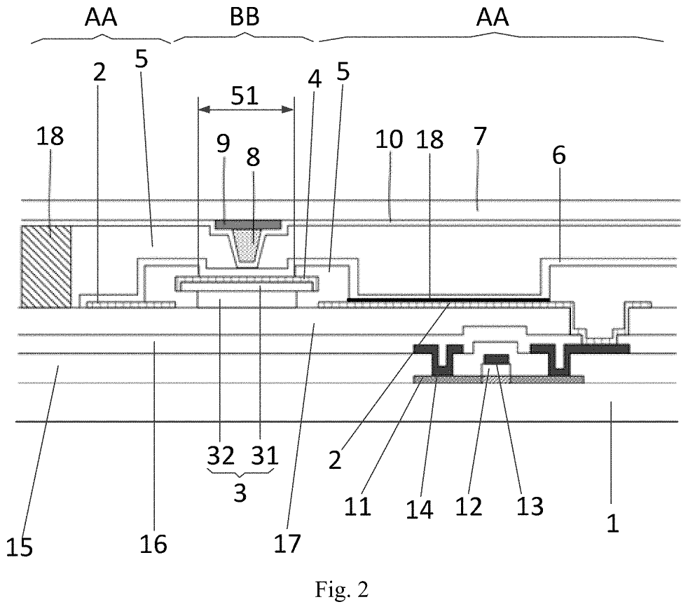

In some embodiments, as shown in FIG. 2, the organic electroluminescent display panel further includes: a package cover plate 7 disposed opposite to the base substrate 1, and a spacer layer 8 on a side of the package cover plate 7 facing the base substrate 1. The spacer layer 8 corresponds to the opening 51. In this way, when the cell aligning process is performed on the package cover plate 7 and the base substrate, the spacer layer 8 is aligned with a part of the reflective portion 4 exposed by the opening 51 of the pixel defining layer 5. With the pressure applied in the cell aligning process, the distance between the reflective portion 4 and the cathode 6 is shortened. The reflective portion 4 is in direct contact with the cathode 6, so that the resistance of the cathode 6 can be reduced. Therefore, the problem of a large voltage drop due to a large resistance of the cathode 6 is avoided, and the problem of damaging the display panel due to the large voltage drop can be avoided. In addition, the deformation amount of the support portion 3 due to the pressure from the spacer layer 8 is smaller than that of the pixel defining layer 5. Therefore, after the cell aligning process is performed on the package cover plate 7 and the base substrate, the cathode 6 is not easily broken at the pressing position of the spacer layer 8, which improves the yield of the display panel.

In addition, in order to further reduce the resistance of the cathode 6, as shown in FIG. 2, the above-mentioned organic electroluminescent display panel provided by the embodiment of the present disclosure further includes: an auxiliary electrode 9 and a conductive layer 10. The auxiliary electrode 9 is located between the spacer layer 8 and the package cover plate 7. An area of an orthographic projection of the auxiliary electrode 9 on the base substrate 1 is larger than an area of an orthographic projection of the spacer layer 8 on the substrate 1. The conductive layer 10 is electrically connected to the auxiliary electrode 9 and covers the spacer layer 8 and the package cover plate 7. In this way, when the cell aligning process is performed on the display panel, the auxiliary electrode 9 is in electrical contact with the cathode 6 through the conductive layer 10, thereby further reducing the resistance of the cathode. Therefore, the problem of a large voltage drop due to a large resistance of the cathode 6 is further avoided, and the problem of damaging the display panel due to a large voltage drop can be further avoided.

In specific implementations, in the above-mentioned organic electroluminescent display panel provided by the embodiments of the present disclosure, as shown in FIG. 1 and FIG. 2, the organic electroluminescent display panel further includes a thin film transistor for driving the display panel to emit light. The thin film transistor includes an active layer 11 on the base substrate 1, a gate insulating layer 12 on the active layer 11, a gate 13 on the gate insulating layer 12, and a source/drain electrode 14 electrically connected to the active layer 11. The electroluminescent display panel further includes an interlayer dielectric layer 15 located between the active layer 11 and the source/drain electrode 14, a passivation layer 16 covering the source/drain electrode 14, and a planarization layer 17 located between the passivation layer 16 and the support portion 3. The reflective anode 2 is connected to the source/drain electrode 14 through a via penetrating the passivation layer 16 and the planarization layer 17, which is not limited herein.

In specific implementations, in the above-mentioned organic electroluminescent display panel provided by the embodiment of the present disclosure, as shown in FIG. 2, the organic electroluminescent display panel further includes a frame sealing adhesive 18 located in a frame region of the display panel and used to frame the organic electroluminescent display panel, which is not limited herein.

In specific implementations, the materials of the reflective anode, the reflective portion, the cathode, the auxiliary electrode, and the conductive layer of the present disclosure may be commonly used metal materials, such as Ag, Cu, Al, Mo, etc., or multilayer metals such as MoNb/Cu/MoNb, etc., or alloy materials of the above metals, such as AlNd, MoNb, etc., and may also be a stacked structure such as ITO/Ag/ITO, etc. formed by metals and transparent conductive oxides (e.g., ITO, AZO, etc.), which is not limited herein.

It should be noted that the organic electroluminescent display panel provided by the embodiments of the present disclosure is suitable for device structures such as top-gate TFT, back channel etch (BCE) TFT, and etch stop layer (ESL) TFT.

It should be noted that the embodiments of the present disclosure are applicable to TFTs using various oxides, silicon materials, or organic materials as active layers. The materials of the active layers may include various materials such as a-IGZO, ZnON, IZTO, a-Si, p-Si, hexathiophene, and polythiophene. That is, the embodiments of the present disclosure are applicable to the TFTs on the back panel manufactured based on oxide technology, silicon technology, or organic technology.

The materials of the gate insulating layer, the interlayer dielectric layer, and the passivation layer in the embodiments of the present disclosure include, but are not limited to, conventional dielectric materials such as SiOx, SiNx, and SiON, or various new organic insulating materials, or high dielectric constant (high k) materials such as AlOx, HfOx, TaOx, etc., which are not limited herein.

The material of the planarization layer in the embodiment of the present disclosure includes, but is not limited to, a material having a planarization effect such as a polysiloxane-based material, an acrylic-based material, and a polyimide-based material, which is not limited herein.

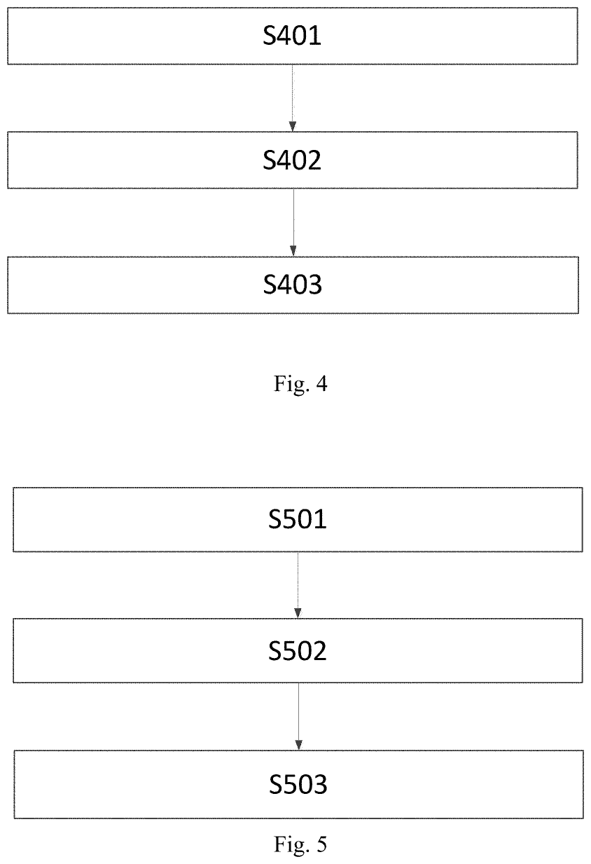

Based on the same concept, an embodiment of the present disclosure also provides a method for manufacturing an organic electroluminescent display panel. As shown in FIG. 4, the method includes the following steps: S401, providing a base substrate including a plurality of pixel regions and a non-pixel region between adjacent pixel regions; S402, forming a support portion in the non-pixel region; and S403, forming a reflective anode in each pixel region and forming a reflective portion on top of the support portion. For each reflective anode and a reflective portion directly adjacent to the reflective anode, a gap is located between the reflective anode and the reflective portion, and an orthographic projection of the reflective anode on the base substrate and an orthographic projection of the reflective portion on the base substrate have a common edge.

According to the method for manufacturing the organic electroluminescent display panel provided by the embodiment of the present disclosure, before the reflective anode is deposited, a support portion is provided in the non-pixel region. Therefore, when the material of the reflective anode is deposited, a gap is automatically formed between the reflective anode and a reflective portion directly adjacent to the reflective anode. The reflective anode is formed in the pixel region, and the reflective portion is formed in the non-pixel region. In this way, the independent reflective anodes are formed; moreover, the reflective anodes and the reflective portions completely cover the multiple pixel regions and the non-pixel region, which improves the light shielding effect on the devices (e.g., the thin film transistors) of the organic electroluminescent display panel and improves the reliability of the organic electroluminescent display panel.

In some embodiments, an area of an orthographic projection of a surface of the support portion facing the reflective portion on the base substrate is larger than an area of an orthographic projection of a surface of the support portion facing away from the reflective portion on the base substrate.

Further, in some embodiments, the support portion includes an upper section and a lower section; the upper section is located between the reflective portion and the lower section. As shown in FIG. 5, the step of forming the support portion in the non-pixel region (i.e., step S402) includes: S501, forming a stacked first dielectric layer and a second dielectric layer in the non-pixel region, the second dielectric layer being between the first dielectric layer and the base substrate; S502, forming the upper section by performing a dry etching process on the first dielectric layer; and S503, forming the lower section by performing a wet etching process on the second dielectric layer using the upper section as a mask pattern. An area of an orthographic projection of the upper section on the base substrate is larger than an area of an orthographic projection of the lower section on the base substrate.

In some embodiments, a material of the second dielectric layer is SiOx, and a material of the first dielectric layer is SiNx.

In the above-mentioned organic electroluminescent display panel provided by the embodiment of the present disclosure, as shown in FIG. 1, the material of the lower section 32 (i.e., the second dielectric layer) is SiOx, and the material of the upper section 31 (i.e., the first dielectric layer) is SiNx. The SiNx material is only longitudinally etched during dry etching, so the dry etching can be used to form the upper section 31 near the reflective portion 4. The SiOx material can be etched laterally during wet etching, so the wet etching can be used to form the lower section 32. Therefore, when the material of the reflective anode is deposited, a gap is automatically formed between the reflective anode and the reflective portion directly adjacent to the reflective anode. The reflective anode is formed in the pixel region, and the reflective portion is formed in the non-pixel region. In this way, the independent reflective anodes are formed; moreover, the reflective anodes and the reflective portions completely cover the multiple pixel regions and the non-pixel region, which improves the light shielding effect on the devices (e.g., the thin film transistors) of the organic electroluminescent display panel and improves the reliability of the organic electroluminescent display panel.

In some embodiments, the step of forming the reflective anode in each pixel region and forming the reflective portion on top of the support portion includes: forming the reflective anode in each pixel region and forming the reflective portion on top of the support portion by using the same patterning process.

According to some embodiments of the present disclosure, the reflective portion and the reflective anode may be formed simultaneously using the same patterning process, thereby further simplifying the manufacturing process.

The method for manufacturing the organic electroluminescent display panel provided by the embodiment of the present disclosure will be described in detail below by taking the structure of the organic electroluminescent display panel shown in FIG. 2 as an example.

The method for manufacturing the organic electroluminescent display panel shown in FIG. 2 may include the following steps.

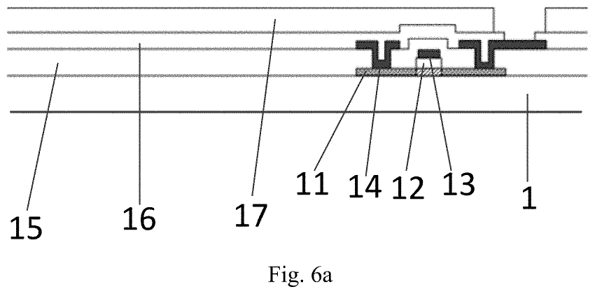

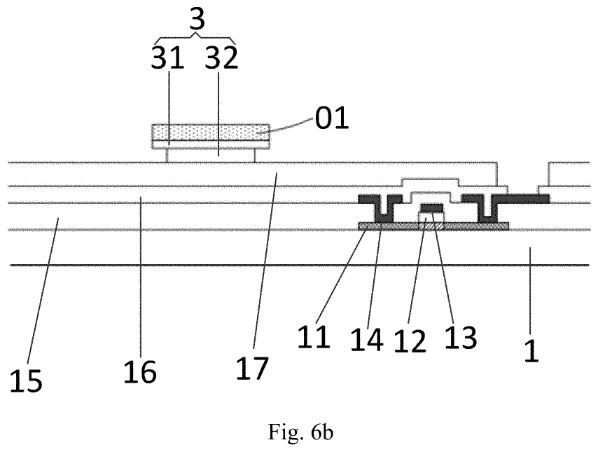

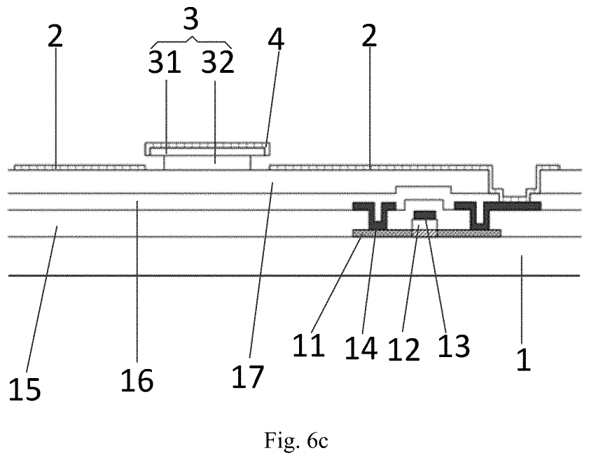

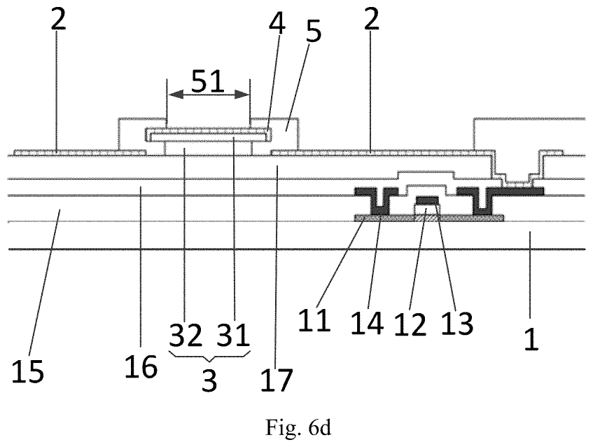

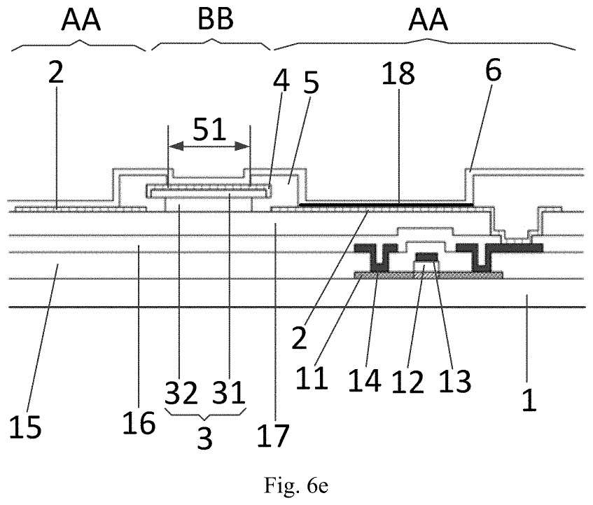

As shown in FIG. 6a, a planarization layer 17 is formed on a base substrate on which a thin film transistor is provided, and a via is formed at a position of the planarization layer 17 corresponding to the source/drain electrode 14 of the thin film transistor.

As shown in FIG. 6b, a first dielectric layer and a second dielectric layer are successively deposited in a non-pixel region of the base substrate 1 on which the planarization layer 17 is formed, and the second dielectric layer is between the first dielectric layer and the base substrate. The thickness of the second dielectric layer may be greater than the thickness of the first dielectric layer. A photoresist 01 is applied on the first dielectric layer near the reflective portion 4, and a dry etching process is performed on the first dielectric layer to form the pattern of the upper section 31. Retaining the photoresist 01 and using the upper section 31 as a mask pattern, a wet etching process is performed on the second dielectric layer to form a pattern of the lower section 32. The area of the orthographic projection of the upper section on the base substrate is larger than the area of the orthographic projection of the lower section on the base substrate. The material of the second dielectric layer may be SiOx, and the material of the first dielectric layer may be SiNx.

As shown in FIG. 6c, a material of a reflective anode is deposited on the base substrate 1 on which the support portion 3 is formed. Due to the existence of the support portion 3 in the non-pixel area, the material of the reflective anode is automatically disconnected in the non-pixel area, the independent reflective anode 2 is formed in the pixel area, and the reflective portion 4 is formed in the non-pixel area. The reflective anode 2 is connected to the source/drain electrode 14 of the thin film transistor through the via in the planarization layer 17.

As shown in FIG. 6d, a pixel defining layer 5 is formed on the base substrate 1 on which the reflective portion 4 is formed. An opening 51 is formed on the pixel defining layer 5 by a photolithography process to expose at least a part of the reflective portion 4. The area of the orthographic projection of the opening 51 on the base substrate 1 is smaller than the area of the orthographic projection of the reflective portion 4 on the base substrate 1.

As shown in FIG. 6e, a light emitting layer 18 is formed on the base substrate 1 on which the pixel defining layer 5 is formed. A cathode 6 is formed on the pixel defining layer 5 and covers the reflective anode 2 and the reflective portion 4.

A cell aligning process is performed on the base substrate 1 shown in FIG. 6e and the package cover plate 7 provided with the spacer layer 8, the auxiliary electrode 9, and the conductive layer 10 by using a frame sealing adhesive. The organic electroluminescent display panel as shown in FIG. 2 can thus be obtained.

It should be noted that, in the above-mentioned manufacturing method provided by the embodiment of the present disclosure, the patterning process may include only a photolithography process, or may include a photolithography process and an etching step, and may also include processes such as printing, inkjet, etc. for forming a predetermined pattern. The photolithography process refers to a process of forming a pattern using a photoresist, a mask, an exposure machine, etc., and including processes such as film formation, exposure, and development. In specific implementations, a corresponding patterning process may be selected according to the structure formed in the present disclosure.

Based on the same concept, an embodiment of the present disclosure also provides a display device. The display device includes the organic electroluminescent display panel according to the above embodiments. The advantages of the display device are similar to the aforementioned organic electroluminescent display panel, and the implementation of the display device can refer to the implementation of the aforementioned organic electroluminescent display panel, which are not repeated herein.

In specific implementations, the display device can be any product or component with display function, such as mobile phone, tablet computer, TV, display, notebook computer, digital photo frame and navigator. Other essential components of the display device should all be possessed as understood by the ordinary skilled person in the art, which will not be repeated here, and should not be taken as limitations to the present disclosure either.

According to the organic electroluminescent display panel, the manufacturing method thereof, and the display device provided by the embodiments of the present disclosure, before the reflective anode is deposited, a support portion is provided in the non-pixel region. Therefore, when the material of the reflective anode is deposited, a gap is automatically formed between the reflective anode and the reflective portion directly adjacent to the reflective anode. The reflective anode is formed in the pixel region, and the reflective portion is formed in the non-pixel region. In this way, the independent reflective anodes are formed; moreover, the reflective anodes and the reflective portions completely cover the multiple pixel regions and the non-pixel region, which improves the light shielding effect on the devices (e.g., the thin film transistors) of the organic electroluminescent display panel and improves the reliability of the organic electroluminescent display panel.

Apparently, the person skilled in the art may make various alterations and variations to the disclosure without departing the spirit and scope of the disclosure. As such, provided that these modifications and variations of the disclosure pertain to the scope of the claims of the disclosure and their equivalents, the disclosure is intended to embrace these alterations and variations.

1. An organic electroluminescent display panel, comprising:
a base substrate comprising a plurality of pixel regions and a non-pixel region between adjacent pixel regions of the plurality of pixel regions,
wherein each pixel region of the plurality of pixel regions comprises a reflective anode,
wherein the non-pixel region comprises a support portion and a reflective portion on top of the support portion,
wherein for each reflective anode and a reflective portion directly adjacent to the reflective anode, a gap is between the reflective anode and the reflective portion, and
wherein an orthographic projection of the reflective anode on the base substrate and an orthographic projection of the reflective portion on the base substrate have a common edge.

2. The organic electroluminescent display panel according to claim 1,
wherein an area of an orthographic projection of a surface of the support portion facing the reflective portion on the base substrate is larger than an area of an orthographic projection of a surface of the support portion facing away from the reflective portion on the base substrate.

3. The organic electroluminescent display panel according to claim 1,
wherein the support portion comprises an upper section and a lower section,
wherein the upper section is between the reflective portion and the lower section, and
wherein an area of an orthographic projection of the upper section on the base substrate is larger than an area of an orthographic projection of the lower section on the base substrate.

4. The organic electroluminescent display panel according to claim 3, wherein a material of the lower section comprises SiOx, and a material of the upper section comprises SiNx.

5. The organic electroluminescent display panel according to claim 1, wherein a material of the reflective portion and a material of the reflective anode are same.

6. The organic electroluminescent display panel according to claim 1, further comprising:
a cathode overlapping the plurality of pixel regions and the non-pixel region,
wherein the cathode and the reflective portion are in direct contact.

7. The organic electroluminescent display panel according to claim 6,
wherein the non-pixel region further comprises a pixel defining layer on the reflective portion,
wherein a portion of the pixel defining layer corresponding to the reflective portion has an opening, and
wherein the cathode directly contacts the reflective portion in the opening.

8. The organic electroluminescent display panel according to claim 7, wherein an area of an orthographic projection of the opening on the base substrate is less than an area of the orthographic projection of the reflective portion on the base substrate.

9. The organic electroluminescent display panel according to claim 7, further comprising:
a package cover plate opposite to the base substrate, and a spacer layer on a side of the package cover plate facing the base substrate,
wherein the spacer layer corresponds to the opening.

10. The organic electroluminescent display panel according to claim 9, further comprising:
an auxiliary electrode; and
a conductive layer,
wherein the auxiliary electrode is between the spacer layer and the package cover plate,
wherein an area of an orthographic projection of the auxiliary electrode on the base substrate is greater than an area of an orthographic projection of the spacer layer on the base substrate, and
wherein the conductive layer is electrically connected to the auxiliary electrode and covers the spacer layer and the package cover plate.

11. A display device comprising the organic electroluminescent display panel according to claim 1.

12. A method for manufacturing an organic electroluminescent display panel, comprising:
providing a base substrate comprising a plurality of pixel regions and a non-pixel region between adjacent pixel regions of the plurality of pixel regions;
forming a support portion in the non-pixel region; and
forming a reflective anode in each pixel region of the plurality of pixel regions and forming a reflective portion on top of the support portion,
wherein for each reflective anode and a reflective portion directly adjacent to the reflective anode, a gap is between the reflective anode and the reflective portion, and
wherein an orthographic projection of the reflective anode on the base substrate and an orthographic projection of the reflective portion on the base substrate have a common edge.

13. The method according to claim 12, wherein an area of an orthographic projection of a surface of the support portion facing the reflective portion on the base substrate is greater than an area of an orthographic projection of a surface of the support portion facing away from the reflective portion on the base substrate.

14. The method according to claim 12,
wherein the support portion comprises an upper section and a lower section,
wherein the upper section is between the reflective portion and the lower section,
wherein forming the support portion in the non-pixel region comprises:
forming a stacked first dielectric layer and a second dielectric layer in the non-pixel region, wherein the second dielectric layer is between the first dielectric layer and the base substrate;
forming the upper section by performing a dry etching process on the first dielectric layer; and
forming the lower section by performing a wet etching process on the second dielectric layer using the upper section as a mask pattern,
wherein an area of an orthographic projection of the upper section on the base substrate is greater than an area of an orthographic projection of the lower section on the base substrate.

15. The method according to claim 14, wherein a material of the second dielectric layer comprises SiOx, and a material of the first dielectric layer comprises SiNx.

16. The method according to claim 12, wherein forming the reflective anode in each pixel region and forming the reflective portion on top of the support portion comprises:
forming the reflective anode in each pixel region and forming the reflective portion on top of the support portion by using a same patterning process.

17. The display device according to claim 11, wherein an area of an orthographic projection of a surface of the support portion facing the reflective portion on the base substrate is greater than an area of an orthographic projection of a surface of the support portion facing away from the reflective portion on the base substrate.

18. The display device according to claim 11,
wherein the support portion comprises an upper section and a lower section,
wherein the upper section is between the reflective portion and the lower section, and
wherein an area of an orthographic projection of the upper section on the base substrate is greater than an area of an orthographic projection of the lower section on the base substrate.

19. The display device according to claim 18, wherein a material of the lower section comprises SiOx, and a material of the upper section comprises SiNx.

20. The display device according to claim 11, wherein a material of the reflective portion and a material of the reflective anode are same.
